(19) United States
(12) Patent Application Publication
(10) Pub. No.: US 2007/0158707 A1
(43) Pub. Date: Jul. 12, 2007

(54) IMAGE SENSOR AND FABRICATING METHOD THEREOF

(76) Inventors: Min-San Huang, Hsinchu (TW); Sian-Min Chung, Taipei County (TW); Chia-Chiang Wang, Taichung County (TW); Yu-Chun Lin, Hsinchu County (TW); Wen-Tsung Chiu, Pingtung County (TW); Hung-Nien Chen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,477

(22) Filed: Mar. 29, 2006

(30) Foreign Application Priority Data
Dec. 28, 2005 (TW) 94146930

(51) Int. Cl. H01L 31/113; H01L 31/062

(52) U.S. Cl. 257/290

(57) ABSTRACT

An image sensor including a substrate, a plurality of conductive sections, a first type doped layer, an intrinsic layer, and a transparent electrode layer is provided. Wherein, the conductive sections are disposed on the substrate, and the dielectric layer is disposed between two adjacent conductive sections. In addition, the first type doped layer overlays the conductive sections and the dielectric layer, and the intrinsic layer is disposed on the first type doped layer. Moreover, the transparent electrode layer is disposed on the intrinsic layer.

### CROSS-REFERENCE TO RELATED APPLICATION

This application claims the priority benefit of Taiwan application serial no. 94146930, filed on Dec. 28, 2005. All disclosure of the Taiwan application is incorporated herein by reference.

### BACKGROUND OF THE INVENTION

1. Field of the Invention

The present invention relates to a semiconductor device and a method thereof, and more particularly, to an image sensor and the fabricating method thereof.

2. Description of the Related Art

The image sensor is an electronic device for converting optical information into telecommunication signal. The image sensor is roughly classified into two different categories as Cathode Ray Tube (CRT) and fixed photograph device. The CRT technique is mainly applied in television (TV) and also widely used for applying the image processing technique in the measuring, controlling, and recognizing application techniques.

FIG. 1 is a cross-sectional view of a conventional positive-intrinsic-negative (PIN) diode image sensor. FIG. 2 is a cross-sectional view of another conventional positive-intrinsic-negative (PIN) diode image sensor. FIG. 3 is a cross-sectional view of yet another conventional positive-intrinsic-negative (PIN) diode image sensor.

Referring to FIG. 1, in the conventional image sensor, the PIN diode comprising a P-doped layer 108, an intrinsic layer 106, and an N-doped layer 104 is electrically connected to an active circuit in a substrate 100 through a plurality of conductive sections 110 and a metal interconnect structure 102; and a transparent electrode layer 112 is disposed on the P-doped layer 108. However, in such image sensor array, there is no insulation between two adjacent image sensors, thus there is leakage current between the conductive sections 110 via the N-doped layer 104.

Some methods for eliminating the current leakage between the image sensors have been disclosed in the prior art. Referring to FIG. 2, a trench 204 is formed between two adjacent image sensors to extend the path on which the current is leaked from the N-doped layer 200 passing through between the conductive sections 206, such that the current leakage is decreased. However, some current may still leak from the N-doped layer 200, and when the current strength between two conductive sections 206 is too big, the current will directly pass through the intrinsic layer 202, which results in current leakage.

In addition, referring to FIG. 3, in the conventional technique, a method has been proposed to use a dielectric layer 304 to isolate two adjacent image sensors, such that each image sensor has its own PIN diode 300 and the conductive sections 302 to resolve the problem of the current leakage between two adjacent image sensors. However, the fabricating method is very complex, which increases the fabricating cost and the production time, and also deteriorates the productiveness.

### SUMMARY OF THE INVENTION

Therefore, it is an object of the present invention to provide an image sensor that can effectively prevent current leakage between image sensors.

It is another object of the present invention to provide a method for fabricating an image sensor in which the electric filed between two image sensors is effectively isolated.

The present invention provides an image sensor, which comprises a substrate, a plurality of conductive sections, a first type doped layer, an intrinsic layer, and a transparent electrode layer. Wherein, the conductive sections are disposed on the substrate, and the dielectric layer is disposed between two adjacent conductive sections. In addition, the first type doped layer overlays the conductive sections and the dielectric layer, and the intrinsic layer is disposed on the first type doped layer. Moreover, the transparent electrode layer is disposed on the intrinsic layer.

In accordance with a preferred embodiment of the present invention, the image sensor further comprises a second type doped layer that is disposed between the intrinsic layer and the transparent electrode layer.

In the image sensor according to a preferred embodiment of the present invention, the first type doped layer is an N-doped layer, and the second type doped layer is a P-doped layer.

In the image sensor according to a preferred embodiment of the present invention, the first type doped layer is a P-doped layer, and the second type doped layer is an N-doped layer.

In the image sensor according to a preferred embodiment of the present invention, the second type doped layer is made of a material such as a-Si (amorphous silicon).

In the image sensor according to a preferred embodiment of the present invention, the transparent electrode layer is made of a material such as ITO (indium-tin oxide).

In the image sensor according to a preferred embodiment of the present invention, the conductive sections are made of a material such as metal.

In the image sensor according to a preferred embodiment of the present invention, the first type doped layer and the intrinsic layer are made of a material such as a-Si (amorphous silicon).

In the image sensor according to a preferred embodiment of the present invention, the substrate comprises an active circuit.

In the image sensor according to a preferred embodiment of the present invention, the active circuit comprises a CMOS (Complementary Metal Oxide Semiconductor).

In accordance with a preferred embodiment of the present invention, the image sensor further comprises a metal interconnect structure that is disposed between the substrate and the conductive sections, and the metal interconnect structure electrically connects the conductive sections to the active circuit.

The present invention further provides a method for fabricating an image sensor, which comprises the following steps. First, a substrate is provided. Then, a dielectric layer is formed on the substrate, and a plurality of openings is formed in the dielectric layer to expose the substrate. Then, a conductive layer is formed on the dielectric layer to fill the openings, and the conductive layer disposed outside of the openings is removed, so as to form a conductive section in each opening. Then, a first type doped layer is formed on the substrate to overlay the conductive sections and the dielectric layer. Afterwards, an intrinsic layer is formed on the first type doped layer. Finally, a transparent electrode layer is formed on the intrinsic layer.

In accordance with a preferred embodiment of the present invention, the method for fabricating the image sensor further comprises: forming a second type doped layer between the intrinsic layer and the transparent electrode layer.

In the method for fabricating the image sensor according to a preferred embodiment of the present invention, the method for forming the second type doped layer comprises a Chemical Vapor Deposition (CVD) process.

In the method for fabricating the image sensor according to a preferred embodiment of the present invention, the first type doped layer is an N-doped layer, and the second type doped layer is a P-doped layer.

In the method for fabricating the image sensor according to a preferred embodiment of the present invention, the first type doped layer is a P-doped layer, and the second type doped layer is an N-doped layer.

In the method for fabricating the image sensor according to a preferred embodiment of the present invention, the method for removing the conductive layer disposed outside of the openings comprises a Chemical Mechanical Polishing (CMP) process.

In the method for fabricating the image sensor according to a preferred embodiment of the present invention, the method for forming the first type doped layer comprises a Chemical Vapor Deposition (CVD) process.

In the method for fabricating the image sensor according to a preferred embodiment of the present invention, the method for forming the intrinsic layer comprises a Chemical Vapor Deposition (CVD) process.

In the method for fabricating the image sensor according to a preferred embodiment of the present invention, the method for forming the transparent electrode layer comprises a Physical Vapor Deposition (PVD) process.

In the present invention, a dielectric layer is disposed between two adjacent conductive sections in the image sensor to isolate the conductive sections, which effectively blocks the electric field between two adjacent image sensors and prevents the current from being leaked. Moreover, the method for fabricating the image sensor provided by the present invention is rather simple, which avoids the problems of fabricating cost increase and productivity deterioration.

### BRIEF DESCRIPTION OF THE DRAWINGS

The accompanying drawings are included to provide a further understanding of the invention, and are incorporated in and constitute a portion of this specification. The drawings illustrate embodiments of the invention, and together with the description, serve to explain the principles of the invention.

FIG. 1 is a cross-sectional view of a conventional positive-intrinsic-negative (PIN) diode image sensor.

FIG. 2 is a cross-sectional view of another conventional positive-intrinsic-negative (PIN) diode image sensor.

FIG. 3 is a cross-sectional view of yet another conventional positive-intrinsic-negative (PIN) diode image sensor.

FIGS. 4A˜4D are the cross-sectional views illustrating a method for fabricating an image sensor according to an embodiment of the present invention.

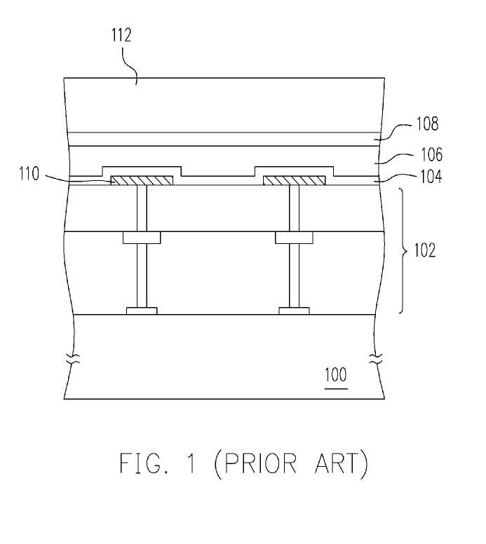

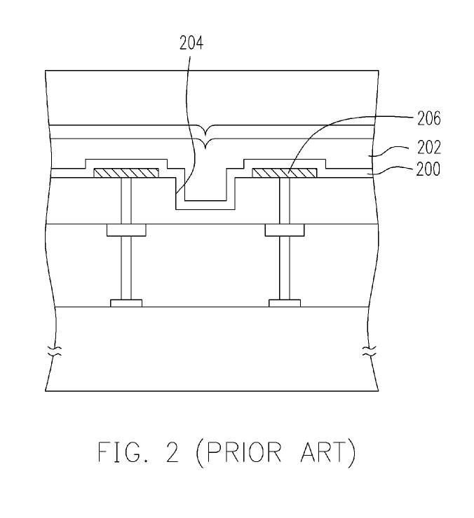

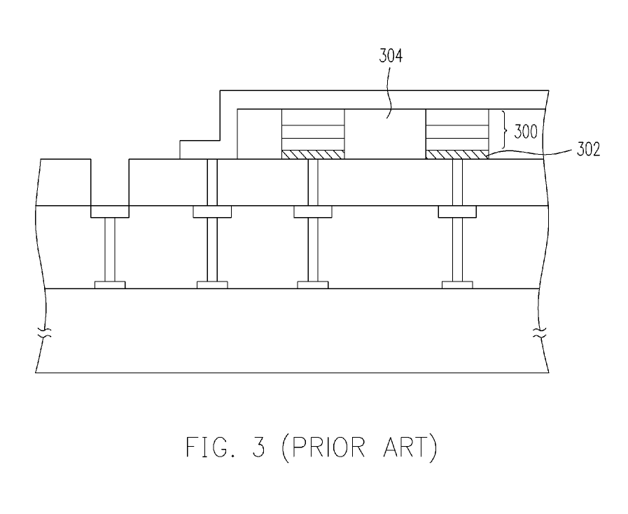

### DESCRIPTION OF THE PREFERRED EMBODIMENTS

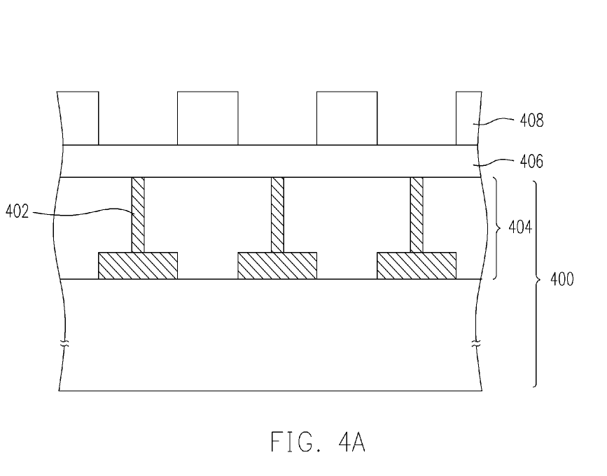

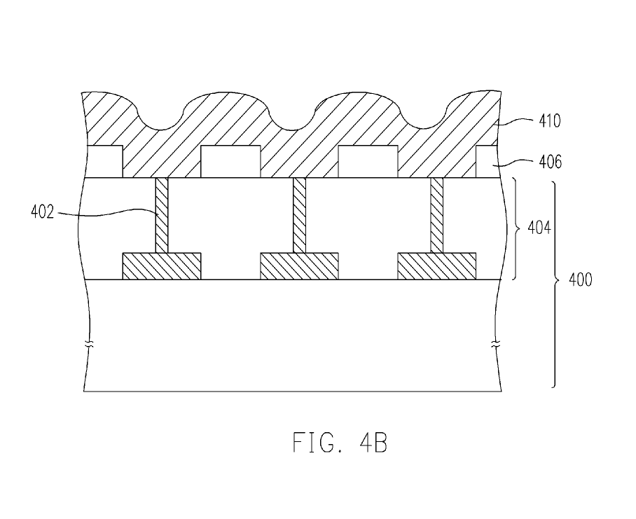

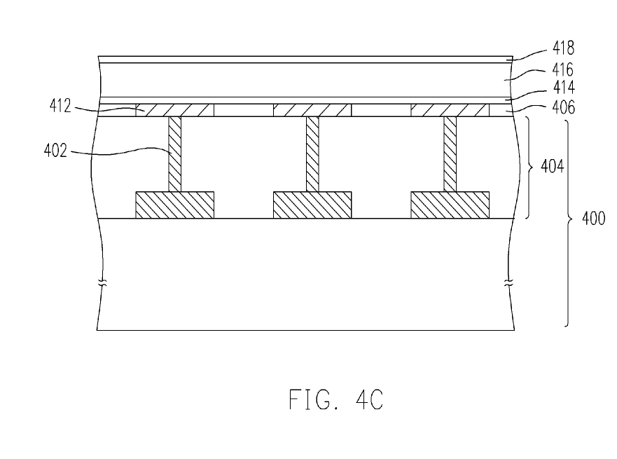

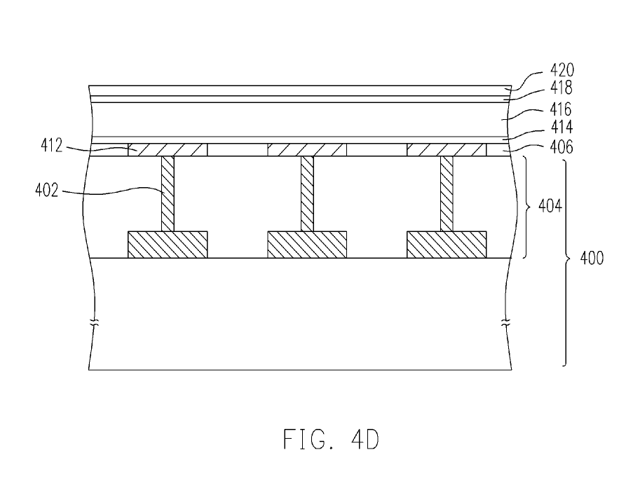

FIGS. 4A˜4D are the cross-sectional views illustrating a method for fabricating an image sensor according to an embodiment of the present invention.

Referring to FIG. 4A, first a substrate 400 is provided, wherein the substrate 400 may be a silicon substrate. An active circuit (not shown) composed of an active device such as a CMOS and a metal interconnect structure 404 composed of an intra connection component such as a contact 402 are formed in the substrate 400. Wherein, the active circuit is configured to detect the conductivity of the image sensor, and the metal interconnect structure 404 connects the active device to the diode component that is subsequently formed on the substrate 400. Both of the active circuit and the metal interconnect structure formed in the substrate 400 are well known to the one of the ordinary skills in the art, thus its detail is omitted herein.

Then, a dielectric layer 406 is formed on the substrate 400. Here, the dielectric layer 406 is made of a material such as silicon nitride and formed by a Chemical Vapor Deposition (CVD) process. Afterwards, a patterned photoresist layer 408 is formed on the dielectric layer 406.

Then, referring to FIG. 4B, a plurality of openings (including a conductive layer 410 and a photoresist 408) is formed in the dielectric layer 406 to expose the contact 402 of the substrate 400. The method for forming the openings is as follows: first, using the patterned photoresist layer 408 as a photomask to perform an anisotropic etching process on the dielectric layer 406; and then removing the patterned photoresist layer 408.

Then, a conductive layer 410 is formed on the dielectric layer 406 to fill the openings. Here, the conductive layer 410 is made of TiN or other appropriate material and formed by a Physical Vapor Deposition (PVD) process, such as a sputtering deposition process.

Then, referring to FIG. 4C, the conductive layer 410 disposed outside of the openings is removed, so as to form the conductive section 412 that is electrically connected to the contact 402 in each opening. The method for removing the conductive layer 410 outside of the openings comprises: using the electric layer 406 as a polish stop to perform a Chemical Mechanical Polishing (CMP) process on the conductive layer 410.

Then, an N-doped layer 414 is formed on the substrate, wherein the N-doped layer 414 overlays the conductive section 412 and the dielectric layer 406. The N-doped layer 414 is made of a material such as a-Si (amorphous silicon) and formed by using phosphorus (P) as a dopant to perform a Chemical Vapor Deposition (CVD) process with an in situ doping method. Here, the Chemical Vapor Deposition (CVD) process for forming the N-doped layer 414 may be a Plasma-Enhanced Chemical Vapor Deposition (PECVD) process.

Then, an intrinsic layer 416 is formed on the N-doped layer 414. The intrinsic layer 416 is made of a material such as a-Si (amorphous silicon) and formed by a Chemical Vapor Deposition (CVD), such as a Plasma-Enhanced Chemical Vapor Deposition (PECVD) process. The intrinsic layer 416 is formed under a suitable low temperature environment, so that hydrogen (H) can be reserved in the intrinsic layer 416.

Then, a P-doped layer 418 is optionally formed on the intrinsic layer 416. The P-doped layer 418 is made of a material such as a-Si (amorphous silicon) and formed by using boron (B) as a dopant to perform a Chemical Vapor Deposition (CVD) process with an in situ doping method. Here, the Chemical Vapor Deposition (CVD) process for forming the P-doped layer 418 may be a Plasma-Enhanced Chemical Vapor Deposition (PECVD) process.

Furthermore, referring to FIG. 4D, a transparent electrode layer 420 is formed on the P-doped layer 418. The transparent electrode layer 420 is made of a material such as ITO (indium tin oxide) and formed by a Physical Vapor Deposition (PVD) process, such as a sputtering deposition process. In addition, before forming the transparent electrode 420, a patterning process is performed on the P-doped layer 418, the intrinsic layer 416, and the N-doped layer 414 in order to remove the P-doped layer 418, the intrinsic layer 416, and the N-doped layer 414 that are disposed outside of the pixel region.

In the method for fabricating the image sensor provided by the present invention, since a dielectric layer 406 is formed between two conductive sections 412, the electric field between two adjacent image sensors is isolated, such that the leakage current occurred between two adjacent image sensors is effectively restrained. Moreover, the process for fabricating the image sensor provided by the present invention is rather simple, such that the fabricating cost will not be increased and the productivity will not be decreased.

Referring to FIG. 4D, the image sensor of the present invention comprises a substrate 400, a plurality of conductive sections 412, an N-doped layer 414, an intrinsic layer 416, and a transparent electrode layer 420. Wherein, the substrate 400 comprises an active circuit that is composed of an active device such as a CMOS (Complementary Metal Oxide Semiconductor) and a metal interconnect structure 404 that is composed of an intra-connection component such as a contact 402. The metal interconnect structure 404 connects the active device to the conductive sections 412 disposed on the substrate 400. In addition, a dielectric layer 406 is disposed between two adjacent conductive sections 412. The N-doped layer 414 overlays the conductive section 412 and the dielectric layer 406. The intrinsic layer 416 is disposed on the N-doped layer 414. The transparent electrode layer 420 is disposed on the intrinsic layer 416. In addition, a P-doped layer 418 is disposed between the intrinsic layer 416 and the transparent electrode layer 420. The material and method for forming each layer and component are described in great detail above, thus its detail is omitted herein.

The diode used in the embodiments mentioned above is a PIN (positive-intrinsic-negative) diode comprising the P-doped layer 418, the intrinsic layer 416, and the N-doped layer 414 from the top to the bottom. However, the present invention is not limited by it. It will be apparent to one of the ordinary skills in the art that the present invention can also be applied in the image sensor formed by an NIP (negative-intrinsic-positive) diode comprising an N-doped layer, an intrinsic layer, and a P-doped layer from the top to the bottom.

In the image sensor provided by the present invention, a dielectric layer 406 is formed between two adjacent conductive sections 412, such that the electric field between two adjacent image sensors is isolated and the leakage current is effectively restrained.

In summary, the present invention at least has the following advantages:

1. A dielectric layer is disposed between the image sensors of the present invention to isolate the conductive sections, such that the leakage current occurred between two adjacent image sensors is effectively eliminated.

2. The process for fabricating the image sensor provided by the present invention is rather simple, such that the fabricating cost will not be increased and the production yield will not be decreased.

Although the invention has been described with reference to a particular embodiment thereof, it will be apparent to one of the ordinary skills in the art that modifications to the described embodiment may be made without departing from the spirit of the invention. Accordingly, the scope of the invention will be defined by the attached claims not by the above detailed description.

What is claimed is:

1. An image sensor, comprising:
a substrate;
a plurality of conductive sections disposed on the substrate;
a dielectric layer disposed between the two adjacent conductive sections;
a first type doped layer overlaying the conductive sections and the dielectric layer;
an intrinsic layer disposed on the first type doped layer; and
a transparent electrode layer disposed on the intrinsic layer.

2. The image sensor of claim 1 further comprising a second type doped layer disposed between the intrinsic layer and the transparent electrode layer.

3. The image sensor of claim 2, wherein the first type doped layer is an N-doped layer, and the second type doped layer is a P-doped layer.

4. The image sensor of claim 2, wherein the first type doped layer is a P-doped layer, and the second type doped layer is an N-doped layer.

5. The image sensor of claim 2, wherein the second type doped layer is made of a material including a-Si (amorphous silicon).

6. The image sensor of claim 1, wherein the transparent electrode layer is made of a material including ITO (indium-tin oxide).

7. The image sensor of claim 1, wherein the conductive sections are made of a material including metal.

8. The image sensor of claim 1, wherein the first type doped layer and the intrinsic layer are made of a material including a-Si (amorphous silicon).

9. The image sensor of claim 1, wherein the substrate comprises an active circuit disposed thereon.

10. The image sensor of claim 9, wherein the active circuit comprises a CMOS (Complementary Metal Oxide Semiconductor).

11. The image sensor of claim 9 further comprising a metal interconnect structure disposed between the substrate and the conductive sections, and the metal interconnect structure electrically connecting the conductive sections to the active circuit.

12. A method for fabricating an image sensor, comprising:
providing a substrate;
forming a dielectric layer on the substrate, and the dielectric layer comprising a plurality of openings to expose the substrate;
forming a conductive layer on the dielectric layer to fill the openings;
removing the conductive layer disposed outside of the openings to form a conductive section in each opening;
forming a first type doped layer on the substrate, and the first type doped layer overlaying the conductive sections and the dielectric layer;
forming an intrinsic layer on the first type doped layer; and
forming a transparent electrode layer on the intrinsic layer.

13. The method for fabricating the image sensor of claim 12, further comprising: forming a second type doped layer between the intrinsic layer and the transparent electrode layer.

14. The method for fabricating the image sensor of claim 13, wherein the method for forming the second type doped layer comprises a Chemical Vapor Deposition (CVD) process.

15. The method for fabricating the image sensor of claim 13, wherein the first type doped layer is an N-doped layer, and the second type doped layer is a P-doped layer.

16. The method for fabricating the image sensor of claim 13, wherein the first type doped layer is a P-doped layer, and the second doped layer is an N-doped layer.

17. The method for fabricating the image sensor of claim 12, wherein the method for removing the conductive layer disposed outside of the openings comprises a Chemical Mechanical Polishing (CMP) process.

18. The method for fabricating the image sensor of claim 12, wherein the method for forming the first type doped layer comprises a Chemical Vapor Deposition (CVD) process.

19. The method for fabricating the image sensor of claim 12, wherein the method for forming the intrinsic layer comprises a Chemical Vapor Deposition (CVD) process.

20. The method for fabricating the image sensor of claim 12, wherein the method for forming the transparent electrode layer comprises a Physical Vapor Deposition (PVD) process.
